(19) United States
(12) Patent Application Publication
(10) Pub. No.: US 2023/0275557 A1
(43) Pub. Date: Aug. 31, 2023

(54) Systems And Methods Resulting From The Parametric Coupling Of Mechanical And Electrical Resonator Assemblies And Systems And Methods To Parametrically Couple The Assemblies

(71) Applicant: Georgia Tech Research Corporation, Atlanta, GA (US)

(72) Inventors: Fahrettin Levent Degertekin, Atlanta, GA (US); Sushruta Shashidhara Surappa, Atlanta, GA (US)

(21) Appl. No.: 18/309,847

(22) Filed: May 1, 2023

Related U.S. Application Data
(63) Continuation-in-part of application No. 16/038,137, filed on Jul. 17, 2018, now Pat. No. 11,641,168.
(60) Provisional application No. 62/533,285, filed on Jul. 17, 2017.
(60) Provisional application No. 63/378,915, filed on Oct. 10, 2022.

(51) Int. Cl. H03H 9/02; H03H 9/24

(52) U.S. Cl. CPC H03H 9/02259; H03H 9/2426

(57) ABSTRACT

A resonator-based comb generation system configured for stable frequency comb generation in a media environment across a range of media environment densities. A system configured for frequency comb generation in a media environment across a range of media environment densities can include a resonant mechanical assembly and a resonant electrical assembly, wherein the assemblies are non-linearly coupled. A microelectromechanical (MEM) resonator can be parametrically coupled to a resonant electrical circuit to serve as an electromechanical comb generation system.

### CROSS-REFERENCE TO RELATED APPLICATIONS

This Application is a continuation-in-part of U.S. patent application Ser. No. 16/038,137 filed 17 Jul. 2018, which claims the benefit of U.S. Provisional Patent Application No. 62/533,285 filed 17 Jul. 2017, the contents of each hereby incorporated in its entirety as if fully set forth herein. This Application also claims the benefit of U.S. Provisional Patent Application No. 63/378,915 filed 10 Oct. 2022, the content of which is hereby incorporated in its entirety as if fully set forth herein.

### STATEMENT REGARDING FEDERALLY SPONSORED RESEARCH OR DEVELOPMENT

This invention was made with government support under Award Nos. EB019098 and 1936776 awarded by the National Science Foundation. The government has certain rights in the invention.

### SEQUENCE LISTING

Not Applicable

### STATEMENT REGARDING PRIOR DISCLOSURES BY THE INVENTOR OR A JOINT INVENTOR

Not Applicable

### BACKGROUND OF THE DISCLOSURE

### 1. Field of the Disclosure

This disclosure relates generally to mechanical frequency comb generation, and more specifically, to the parametric coupling of a resonant mechanical assembly (microelectromechanical (MEM)) to a resonant electrical assembly (circuit) that serves as the electromechanical comb generation system.

### 2. Background

A resonator is a device or system that exhibits resonance or resonant behavior. That is, it naturally oscillates with greater amplitude at some frequencies, called resonant frequencies, than at other frequencies. As used herein, the oscillations in a mechanical resonator/mechanical resonator assembly are mechanical (including acoustic), while the oscillations in an electrical resonator/electrical resonator assembly are electromagnetic.

Resonators are used to either generate waves of specific frequencies or to select specific frequencies from a signal. For example, musical instruments use acoustic resonators that produce sound waves of specific tones. Another example is quartz crystals used in electronic devices such as radio transmitters and quartz watches to produce oscillations of very precise frequency.

Parametric resonance is the physical phenomenon where an external excitation, at a specific frequency and typically orthogonal to the plane of displacement, introduces a periodic modulation in one of the system parameters resulting in a buildup in oscillatory amplitude. The first order or the principal parametric resonance is achieved when the driving/excitation frequency is twice the natural frequency of a given system. Higher orders of parametric resonance are observed either at or at submultiples of the natural frequency. For direct resonance, the response frequency always matches the excitation frequency. However, regardless of which order of parametric resonance is activated, the response frequency of parametric resonance is always in the vicinity of the natural frequency.

A parametric resonator can be generally described as a driven harmonic oscillator in which the oscillations are driven by varying a physical parameter of a system element at a pump frequency to induce oscillations in the system. A simple example of a parametric oscillator is a child pumping a swing in motion by periodically standing and squatting at key points in the swing arc to change the moment of inertia of the swing. An analogue example of direct resonance is the child rocking back and forth to pump the swing. While rocking back and forth, the child can cause the swing to move even if the swing is at rest; however, standing and squatting while the swing is at rest only alters a physical parameter of the swing and does not by itself initiate oscillations.

The concept of parametrically coupling a mechanical and electrical resonator has been previously exploited for wireless power transfer and vibration control, where it was found that the initiation threshold for parametric resonance could be lowered by reducing the electrical resistance of the system—a relatively challenging task in purely mechanical parametrically coupled systems.

Wireless power transfer systems, devices, and methods generally include an externally powered type transducer that can function as a pump for a parametric resonator electrical circuit, and the parametric resonator can sustain a resonating electrical signal absent a DC bias, electrical charge, or other external power source applied to the transducer. Such systems, devices, and methods can have applications in many fields, including some of the example implantable medical device applications, wherein a capacitive micromachined ultrasonic transducer can be used as a pump for a parametric resonator to convert acoustic energy from an ultrasonic source to a sustained electrical signal.

In another field, frequency combs comprise a set of equally spaced, coherent spectral lines that take the form of pulse-train in the time domain and resemble the teeth of a comb in the frequency domain. Originally developed as a laser-based tool, optical frequency combs have enabled significant advances in fundamental science and applications such as absolute distance measurement, spectroscopy, communication, frequency metrology, and quantum computing.

More recently, there has been a push to realize the mechanical or phononic equivalent of these optical frequency combs. The development of a set of stable, broadband mechanical frequency combs would enable the use of comb technology in ambient environments in media other than air, like in water and other biologic fluids, which typically reflect or strongly attenuate light.

The generation of such mechanical frequency combs has been demonstrated in various micro and nanoscale systems by taking advantage of non-linear modal interactions at small length scales. When subjected to a strong driving force, the different vibrational modes of a mechanical resonator are coupled to each other via intrinsic non-linearities leading to the formation of frequency combs.

Mechanical frequency combs have been reported using both single and multiple drive tones, and by coupling two or more vibrational modes in a single resonator. However, most efforts to date have either been restricted to comb generation in high-Q resonators at low temperatures and pressures or to a narrow frequency band confined within the vibrational mode of the resonator, primarily because the parametric mode coupling that governs comb generation is damping dependent and requires low loss to efficiently enable coupling between the different mechanical modes.

Furthermore, great care is required to precisely engineer a mechanical frequency comb such that the various mechanical modes display a commensurate resonance frequency relationship required for parametric excitation. These characteristics are especially limiting for applications in liquid, where resonators are typically subjected to large mechanical damping.

Narrowband frequency comb generation can also be limiting in metrology applications where a larger bandwidth enables more accurate range measurement. For all of these reasons and others, mechanical frequency combs have only been used in a limited number of practical applications.

Thus, a need exists for systems and methods for mechanical or phononic equivalents of optical frequency combs, that can be on the macro-scale, that are not limited to high-Q resonators at low temperatures and pressures, or tailored to a narrow frequency band, and that is not limited to successful operation only in air/gas. It is to such a beneficial electromechanical comb generation system, resulting from the parametric coupling of a mechanical resonator assembly and an electrical resonator assembly, that the invention is primarily directed. The present systems and methods provide beneficial results, including advances in mechanical frequency comb generation.

### BRIEF SUMMARY OF THE DISCLOSURE

The present invention is a significantly different approach to conventional mechanical frequency comb generation. In any of the exemplary embodiments, a microelectromechanical (MEM) resonator parametrically coupled to a resonant electrical circuit serves as an electromechanical comb generation system.

One beneficial attribute of the present invention utilizing the parametric coupling of a mechanical and electrical resonator is that the initiation threshold for parametric resonance can be lowered by reducing the electrical resistance of the system—a very challenging task in purely mechanical parametrically coupled systems as those of skill in the art appreciate.

The influence of mechanical damping on the input forcing threshold can be minimized by reducing the circuit electrical losses, enabling the generation of frequency combs in relatively light (air) and relatively heavy (liquid) damped environments.

In an exemplary embodiment of the present invention, a resonator-based comb generation system is configured for stable frequency comb generation in a media environment across a range of media environment densities.

In any of the exemplary embodiments, the system can be configured for stable frequency comb generation in the media environment having a density ranging from about 900 to about 1100.

In any of the exemplary embodiments, the system can comprise a coupled resonant mechanical assembly and resonant electrical assembly.

In any of the exemplary embodiments, the system can comprise a non-linearly coupled resonant mechanical assembly and resonant electrical assembly.

In any of the exemplary embodiments, the system can comprise a resonant mechanical assembly coupled to two or more resonant electrical assemblies.

In any of the exemplary embodiments, the system can be driven to parametric resonance.

In any of the exemplary embodiments, the system can be driven to parametric resonance by an input selected from the group consisting of a mechanical input, an audio input, and a combination thereof.

In any of the exemplary embodiments, an initiation threshold for parametric resonance can be variable.

In any of the exemplary embodiments, an initiation threshold for parametric resonance can be lowered by reducing an electrical resistance of the system.

In another exemplary embodiment of the present invention, a system configured for frequency comb generation in a media environment across a range of media environment densities comprises a resonant mechanical assembly and a resonant electrical assembly, wherein the assemblies are non-linearly coupled.

In any of the exemplary embodiments, the system can be driven to parametric resonance, wherein an initiation threshold for parametric resonance can be selected form the group consisting of being variable, being lowered by reducing an electrical resistance of the system, and a combination thereof.

In any of the exemplary embodiments, the system can be driven to parametric resonance by an input selected from the group consisting of a mechanical input, an audio input, and a combination thereof.

In any of the exemplary embodiments, the system can further comprise a driving mechanism configured to drive the system into parametric resonance.

In any of the exemplary embodiments, the system can further comprise a second resonant electrical assembly, wherein each resonant electrical assembly can be non-linearly coupled to the resonant mechanical assembly.

In any of the exemplary embodiments, the frequency combs can be selected from the group consisting of acoustic frequency combs, mechanical frequency combs, phononic frequency combs, and a combination thereof.

In any of the exemplary embodiments, the resonant mechanical assembly can comprise a microelectromechanical (MEM) resonator, and wherein the resonant electrical assembly can comprise a resonant electrical circuit.

In another exemplary embodiment of the present invention, an electromechanical system for frequency comb generation comprises a coupled resonant mechanical assembly and resonant electrical assembly, wherein the system is configured to generate stable frequency combs while operating in a media environment across a range of media environment densities, and wherein the system is driven to parametric resonance by one or more inputs.

In any of the exemplary embodiments, the system can be configured to generate stable frequency combs while operating in the media environment having a media environment density greater than about 1.2 kg/m³.

In any of the exemplary embodiments, the system can be configured to generate stable frequency combs while operating in the media environment having a media environment density greater than about 10 kg/m³.

In any of the exemplary embodiments, the system can be configured to generate stable frequency combs while operating in the media environment having a media environment density greater than about 50 kg/m³.

In any of the exemplary embodiments, the system can be configured to generate stable frequency combs while operating in the media environment having a density ranging from about 900 kg/m³ to about 1100 kg/m³.

In any of the exemplary embodiments, the resonant electrical assembly can comprise an RLC circuit.

In any of the exemplary embodiments, one or more of the inputs can drive an electrical parameter of the resonant electrical assembly.

In any of the exemplary embodiments, one or more of the inputs can drive a voltage of the resonant electrical assembly.

In any of the exemplary embodiments, one or more of the resonant mechanical assembly and resonant electrical assembly can be non-linearly coupled, the system can further comprise a second resonant electrical assembly, each resonant electrical assembly can be coupled to the resonant mechanical assembly, a mechanical resonance frequency of the resonant mechanical assembly can be approximately equal to twice an electrical resonance frequency of the resonant electrical assembly, the system can be configured to generate stable frequency combs in a liquid, one of the inputs can be selected from the group consisting of a mechanical input, an audio input, and a combination thereof, an initiation threshold for parametric resonance can be selected form the group consisting of being variable, being lowered by reducing an electrical resistance of the system, and a combination thereof, and the frequency combs can be selected from the group consisting of acoustic frequency combs, mechanical frequency combs, phononic frequency combs, and a combination thereof.

In any of the exemplary embodiments, the system can further comprise a driving mechanism configured to drive the system into parametric resonance, wherein the resonant mechanical assembly can comprise a MEM resonator, wherein the resonant electrical assembly can comprise a resonant electrical circuit comprising electrical elements, wherein the MEM resonator can terminate with one or more of the electrical elements of the resonant electrical circuit, and wherein the driving mechanism can drive one or more of the electrical elements with one or more electrical tones.

In any of the exemplary embodiments, the resonant mechanical assembly can have a mechanical Q-factor in the media environment, wherein the resonant electrical assembly can have an electrical Q-factor in the media environment, and wherein the system can be configured to generate the stable frequency combs while operating in the media environment in a range of mechanical Q-factor from about 25 to about 200.

In any of the exemplary embodiments, the system can be configured to generate the stable frequency combs while operating in the media environment in a range of mechanical Q-factor lower than 100.

In any of the exemplary embodiments, the present invention terminates the MEM resonator with a series inductor and drives it with a single electrical tone to generate evenly spaced, coherent electromechanical frequency combs.

In another exemplary embodiment of the present invention, an electro-mechanical device can generate acoustic or phononic frequency combs using a single input electrical drive or dual electrical drive. In this exemplary embodiment, the present device comprises a capacitive MEMS resonator that is electrically terminated with an inductor and resistor, thereby forming a coupled mechanical-electrical resonator. Design parameters can be chosen such that the resonance frequency of the mechanical resonator is approximately two times the resonance frequency of the electrical oscillator. Discrete equally spaced spectral lines or frequency combs are generated when the system is electrically driven close to the electrical resonance frequency, due to parametric coupling between the two resonators. The resistance of the electrical oscillator is tunable and can be tuned to a low value that allows the generation of frequency combs even in mechanically damped environments. It was found that the spacing between the frequency combs is strongly dependent on the force acting on the mechanical resonator—this way, the system can be used as a highly sensitive sensor to detect small changes in force or fluid properties in the surrounding environment.

As the resonance frequency of the electrical oscillator can be controlled by adjusting the value of inductance, the present invention further enables the relatively easy obtainment of the required commensurate frequency relationship between the coupled resonators, independent of the mechanical design and operating conditions.

The present investigation of such a solution starts by introducing a 1-D lumped parameter mathematical model to describe the inventive comb generation system, followed by numerical simulations to investigate the influence of model parameters and operating conditions on the formation of frequency combs.

Experiments were performed using a commercial MEM resonator to validate the numerical results and to demonstrate frequency comb generation in air and in a fluid-filled microfluidic channel. Semi-analytical solutions to the 1-D model indicate that input forcing threshold required to generate evenly spaced frequency combs is a function of both the mechanical and electrical damping, and that the threshold can be lowered by reducing the electrical resistance in the circuit.

Experimental results further confirm that stable frequency combs can be generated in different media with the same MEM resonator, using a single electrical drive tone. The advantages of such comb-based sensor systems over conventional resonant sensors, especially in fluid-sensing applications, is appealing.

In another exemplary embodiment of the present invention, an parametric resonator comprises an electronic device having an electrical parameter configured to oscillate at a pump frequency in response to an applied force to the electronic device, wherein, when the pump frequency is twice a resonance frequency of the parametric resonator, the parametric resonator is configured to generate parametric resonance in response to the oscillating electrical parameter, and sustain an electrical signal responsive to varying the electrical parameter of the electronic device without requiring a permanent charge or a voltage applied to the electronic device, wherein the electronic device is a capacitor having the electrical parameter of capacitance, wherein the capacitance is variable in response to the applied force, wherein, when the pump frequency is twice a resonance frequency of the parametric resonator, the parametric resonator is further configured to sustain the electrical signal responsive to varying the capacitance of the capacitor between a first capacitance that is equal to an average capacitance plus a change in capacitance and a second capacitance that is equal to the average capacitance minus the change in capacitance, and wherein the change in capacitance is equal to or greater than about twice the average capacitance divided by a quality factor of the parametric resonator.

In any of the exemplary embodiments, the parametric resonator can be further configured to generate the electrical signal responsive to varying the capacitance without requiring a permanent charge or a voltage applied to the electronic device.

In any of the exemplary embodiments, the pump frequency can be between about 16 kHz and 100 MHz.

In any of the exemplary embodiments, the applied force can be a mechanical force, and wherein the average capacitance can be a function of the mechanical force acting to vary the capacitance of the capacitor.

In any of the exemplary embodiments, the parametric resonator can form at least a portion of an implantable medical device.

In any of the exemplary embodiments, the capacitor can have a mechanical resonance frequency equal to about twice an electrical resonance frequency of the parametric resonator.

In another exemplary embodiment of the present invention, a parametric resonator system comprises an electronic component of an RLC circuit, wherein the RLC circuit has a resonance frequency, wherein the electronic component has an electrical parameter that oscillates at a pump frequency in response to an external force, wherein, when the pump frequency is twice the resonance frequency of the RLC circuit, the parametric resonator system is configured to self-sustain an oscillating electrical signal in response solely to varying the electrical parameter, wherein the electronic component is a capacitor having the electrical parameter of capacitance, wherein the capacitance is variable in response to the external force, when the pump frequency is twice the resonance frequency of the RLC circuit, the parametric resonator system is further configured to sustain the oscillating electrical signal responsive to varying the capacitance of the capacitor between a first capacitance that is equal to an average capacitance plus a change in capacitance and a second capacitance that is equal to the average capacitance minus the change in capacitance, and wherein the change in capacitance is equal to or greater than about twice the average capacitance divided by a quality factor of the parametric resonator system.

In any of the exemplary embodiments, the system can be configured to self-sustain the oscillating electrical signal without requiring an electrical power source selected from the group consisting of a DC bias, an electrical charge, and external electrical power source.

In any of the exemplary embodiments, the pump frequency can be between about 16 kHz and 100 MHz.

In any of the exemplary embodiments, the capacitor can be a modulated capacitor.

In any of the exemplary embodiments, the parametric resonator system can be configured to sustain the oscillating electrical signal in response to varying the capacitance of the modulated capacitor with the application of an acoustic signal at the pump frequency to the modulated capacitor.

In any of the exemplary embodiments, the pump frequency of the acoustic signal can be about twice a frequency of the oscillating electrical signal.

In any of the exemplary embodiments, the parametric resonator system can further comprise the RLC circuit, and a transmitter for transmitting the external force at the pump frequency.

In another exemplary embodiment of the present invention, a method for electrical transduction comprises generating parametric resonance in a parametric resonator in response to an applied force to an electronic component of the parametric resonator oscillating an electrical parameter of the electronic component of the parametric resonator, and sustaining the parametric resonance in the parametric resonator solely by the applied force oscillating the electrical parameter of the electronic component, wherein a transmitter transmitting the applied force to the electronic component is in wireless communication with the electronic component, wherein the oscillating electrical parameter has a pump frequency that is twice a resonance frequency of the parametric resonator, wherein the electronic component is a capacitor having the electrical parameter of capacitance, wherein the capacitance is variable in response to the applied force, wherein the method further comprises sustaining the parametric resonance responsive to varying the capacitance of the capacitor between a first capacitance that is equal to an average capacitance plus a change in capacitance and a second capacitance that is equal to the average capacitance minus the change in capacitance, and wherein the change in capacitance is equal to or greater than about twice the average capacitance divided by a quality factor of the parametric resonator.

In any of the exemplary embodiments, the applied force can be a mechanical force.

In any of the exemplary embodiments, the method can further comprise applying the applied force to the capacitor, oscillating the capacitance of the capacitor at the pump frequency in response to the mechanical force, and generating an initial oscillation through inductive coupling of the parametric resonator with an electromagnetic signal.

In another exemplary embodiment of the present invention, a parametric resonator comprises a capacitive component having a capacitance that varies in response to an external force, wherein the parametric resonator is configured to sustain an oscillating electrical signal in response to varying the capacitance of the capacitive component with the application of an acoustic signal to the capacitive component, without requiring an electrical power source, wherein the acoustic signal varies the capacitance of the capacitive component between a first capacitance that is equal to an average capacitance plus a change in capacitance and a second capacitance that is equal to the average capacitance minus the change in capacitance, and wherein the change in capacitance is equal to or greater than about twice the average capacitance divided by a quality factor of the capacitive component.

In another exemplary embodiment of the present invention, the parametric resonator can be further configured to oscillate the electrical signal at a resonance frequency responsive to varying the capacitance at a pump frequency that is about twice the resonance frequency.

In another exemplary embodiment of the present invention, a frequency of the acoustic signal can be about twice a frequency of the oscillating electrical signal.

In another exemplary embodiment of the present invention, the pump frequency can be between about 16 kHz and 100 MHz.

In another exemplary embodiment of the present invention, an electromechanical system for frequency comb generation comprising a resonant mechanical assembly, a resonant electrical assembly, and a driving mechanism configured to drive the resonant mechanical assembly and the resonant electrical assembly into parametric resonance, wherein a mechanical resonance frequency of the resonant mechanical assembly of approximately equal to twice an electrical resonance frequency of the resonant electrical assembly, and wherein the electromechanical system is configured to generate frequency combs while operating in a media environment across a range of media environment densities.

In any of the exemplary embodiments, parametric resonance can be reached when the driving mechanism drives the resonant electrical assembly at approximately the electrical resonance frequency.

In any of the exemplary embodiments, the resonant mechanical assembly can comprise a MEM resonator, wherein the resonant electrical assembly can comprise a resonant electrical circuit, wherein the MEM resonator can terminate with a series inductor of the resonant electrical circuit, and wherein the driving mechanism can drive the inductor with a single electrical tone.

In any of the exemplary embodiments, the electromechanical system can be configured to generate frequency combs while operating in a media environment comprising a liquid.

In another exemplary embodiment of the present invention, an electronic device is configured to sustain an electrical signal responsive to varying a capacitance of a capacitor without requiring a permanent charge or a voltage applied to the capacitor.

In any of the exemplary embodiments, the device can be further configured to generate the electrical signal responsive to varying the capacitance without requiring a permanent charge or a voltage applied to the capacitor.

In any of the exemplary embodiments, the capacitance can be variable in response to a mechanical force.

4 In any of the exemplary embodiments, the device can be further configured to sustain the electrical signal responsive to varying the capacitance at frequency that is between about 16 kHz and 100 MHz.

In any of the exemplary embodiments, the device can be further configured to oscillate the electrical signal at an electrical resonance frequency responsive to varying the capacitance at a pump frequency that is equal to about twice the electrical resonance frequency.

In any of the exemplary embodiments, the device can be further configured to sustain the electrical signal responsive to varying the capacitance of the capacitor between a first capacitance that is equal to an average capacitance plus a change in capacitance and a second capacitance that is equal to the average capacitance minus the change in capacitance, wherein the change in capacitance is equal to or greater than about twice the average capacitance divided by a quality factor of the electronic device.

In any of the exemplary embodiments, the average capacitance can be a function of a mechanical force acting to vary the capacitance of the capacitor.

In any of the exemplary embodiments, the device can form at least a portion of an implantable medical device.

In any of the exemplary embodiments, the capacitor can have a mechanical resonance frequency equal to about twice an electrical resonance frequency of the electronic device.

In another exemplary embodiment of the present invention, a parametric resonator comprises an electronic device having an electrical parameter that varies in response to an external force, wherein the parametric resonator is configured to sustain an oscillating electrical signal in response to varying the electrical parameter without requiring an electrical power source.

In any of the exemplary embodiments, the parametric resonator can be configured to oscillate the electrical signal at a resonance frequency responsive to varying the electrical parameter at a pump frequency that is about twice the resonance frequency.

In any of the exemplary embodiments, the pump frequency can be between about 16 kHz and 100 MHz.

In any of the exemplary embodiments, the electronic element can be a modulated capacitor and the electrical parameter is capacitance.

In any of the exemplary embodiments, the parametric resonator can be configured to sustain the oscillating electrical signal in response to varying the capacitance of the modulated capacitor with the application of an acoustic signal to the modulated capacitor.

In any of the exemplary embodiments, a frequency of the acoustic signal can be about twice a frequency of the oscillating electrical signal.

In any of the exemplary embodiments, the acoustic signal can vary the capacitance of the modulated capacitor between a first capacitance that is equal to an average capacitance plus a change in capacitance and a second capacitance that is equal to the average capacitance minus the change in capacitance, wherein the change in capacitance is equal to or greater than about twice the average capacitance divided by a quality factor of the electronic device.

In another exemplary embodiment of the present invention, a method for electrical transduction comprises applying a force to an electronic device of a parametric resonator, oscillating an electrical parameter of the electronic device at a pump frequency in response to the applying the force, generating parametric resonance in the parametric resonator in response the oscillating the electrical parameter, and sustaining the parametric resonance in the parametric resonator without requiring either a power source or a permanent charge applied to the device.

In any of the exemplary embodiments, the force can be a mechanical force and the electronic device is a capacitor.

In any of the exemplary embodiments, the method can further comprise generating the initial oscillation through inductive coupling of the parametric resonator with an electromagnetic signal.

In any of the exemplary embodiments, the pump frequency can be equal to about twice a resonance frequency of the parametric resonator.

Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIG. 1: 1-D lumped parameter representation of the present electromechanical frequency comb generation system according to an exemplary embodiment. The capacitive mechanical resonator is approximated by a baffled parallel plate piston and electrically terminated in series with an inductor, resistor and a voltage source.

FIG. 2A: Top-view of the MEM array used in the experiments with the zoomed inset (FIG. 2B) showing the arrangement of the individual membrane resonators.

FIG. 3: The real and imaginary parts of the impedance measured by connecting two elements in parallel shows a mechanical resonance at 2.6 MHz when biased at 10 VDC.

FIG. 4: Simulated response of the 1-D frequency comb generation model when the input voltage is below and above the critical voltage required for comb generation.

FIG. 5: A 2-D map representing the locations of frequency comb formation in the frequency-forcing space. Here, States 1, 2 and 3 represent stable combs, higher order combs and chaotic combs respectively.

FIG. 6: A 2-D plot obtained using the semi-analytical solution displaying the dependance of comb generation on input voltage (Vᵢₙ) and mechanical quality-factor (Qₘ), where the lighter shaded region represents the existence of frequency combs.

FIG. 7A: Variation of V_{in-crit} as a function of (Qₘ) for decreasing values of Qₑₗ.

FIG. 7B: Frequency spacing between comb lines as a function of Vᵢₙ for different Qₘ.

FIGS. 8A-8B: Voltage measured across the resonator and the corresponding frequency domain representation of combs when Vᵢₙ>V_{crit} for MEM resonator operating in air.

FIG. 9: Increasing spacing between spectral lines observed for larger values of input drive Vᵢₙ.

FIG. 10: Comparison of the numerical and experimentally obtained change in spectral line spacing as a function of input voltage Vᵢₙ. Note that no combs are formed below a drive voltage of 0.4 V in the experiment.

FIG. 11: Experimental set up used to observe frequency combs in liquid.

FIG. 12: Impulse response of the MEM array in FC-70 as recorded by the measurement hydrophone.

FIG. 13: Increasing number of spectral lines spaced apart by 60 kHz for increasing input voltage levels.

FIG. 14: Demonstration of the tunability of generated frequency comb spacing by changing the frequency difference Aw between the two input drive tones.

FIG. 15: Experimental setup to simulate boundary conditions of an enclosed microfluidic channel.

FIG. 16: The effect of channel height d, on the location and spacing between standing wave resonances.

FIG. 17: Electromechanical comb spectrum for increasing input voltage levels when the MEM resonator is operated inside a liquid-filled channel.

FIGS. 18A-18B: Numerical simulation comparing the linear frequency response (FIG. 14A) of an electromechanical resonator in a fluid channel to its frequency comb response when the density of the fluid is reduced by 5%. The change in the frequency spacing between the combs can be seen more clearly as we measure further away from the central spectral line.

### DETAILED DESCRIPTION

Although preferred embodiments of the disclosure are explained in detail, it is to be understood that other embodiments are contemplated. Accordingly, it is not intended that the disclosure is limited in its scope to the details of construction and arrangement of components set forth in the following description or illustrated in the drawings. The disclosure is capable of other embodiments and of being practiced or carried out in various ways. Also, in describing the preferred embodiments, specific terminology will be resorted to for the sake of clarity.

It must also be noted that, as used in the specification and the appended claims, the singular forms “a,” “an” and “the” include plural referents unless the context clearly dictates otherwise.

Also, in describing the preferred embodiments, terminology will be resorted to for the sake of clarity. It is intended that each term contemplates its broadest meaning as understood by those skilled in the art and includes all technical equivalents which operate in a similar manner to accomplish a similar purpose.

Ranges can be expressed herein as from “about” or “approximately” one particular value and/or to “about” or “approximately” another particular value. When such a range is expressed, another embodiment includes from the one particular value and/or to the other particular value.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

The examples disclosed herein illustrate devices, systems and methods for electromechanical frequency comb generation in fluid media with a parametrically driven capacitive microresonator. The present invention relates to the generation of electromechanical frequency combs in both air and liquid environments using a capacitive microresonator array.

In contrast to frequency comb generation in purely mechanical resonators, the present invention recognizes that the damping dependent threshold for comb generation can be reduced by parametrically coupling a resonant electrical circuit to the mechanical resonator.

A 1-D lumped parameter model of an exemplary embodiment is herein presented and semi-analytical solutions developed to investigate the parameters influencing frequency comb formation under various operating conditions. The results obtained with numerical simulations were experimentally validated using a commercially available MEM resonator and frequency combs with a repetition rate sensitive to the force on the mechanical resonator are generated with a single electrical drive in air and in a liquid-filled microfluidic channel.

In inventive contrast to prior work on electromechanical frequency combs, the preset invention represents a robust approach to generating stable combs, thereby enabling its practical use in applications such as gas sensing and microfluidics.

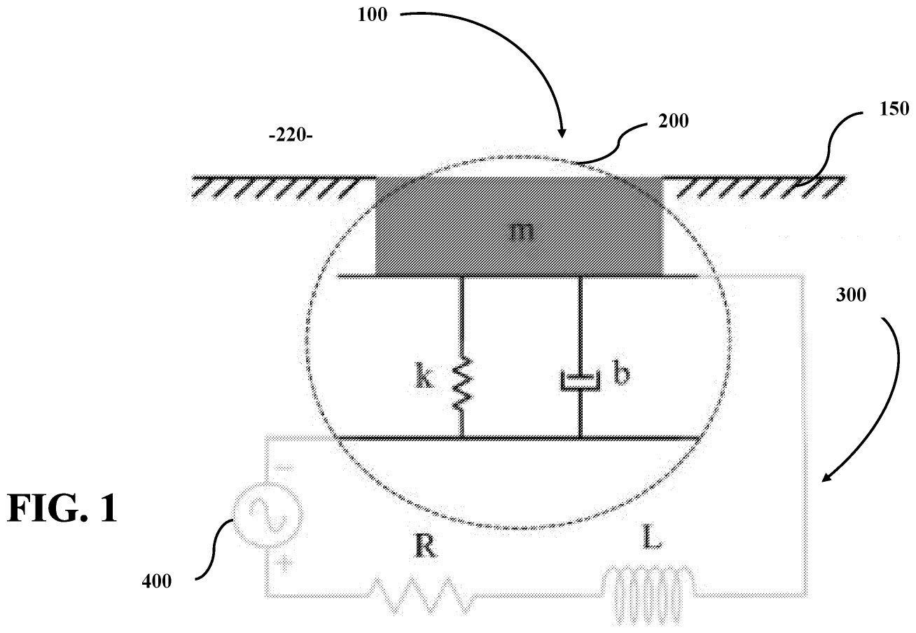

A simplified 1-D lumped parameter model of the present electromechanical frequency comb generation system 100 is illustratively shown in FIG. 1. The present system 100 comprises the parametrical coupling of a mechanical resonating assembly 200 and an electrical resonating assembly 300, driven by a driving mechanism 400.

The mechanical resonating assembly 200 transfers energy repeatedly from kinetic to potential form and back again. Simple mechanical systems include weights-and-springs assemblies, pendulums, and in FIG. 1, specifically a parallel-plate baffled piston. The piston has an equivalent mass m, stiffness k and damping b, and is radiating into a fluid half-space 220. The damping term only includes the radiation losses in the fluid, while the structural losses in the mechanical resonating assembly 200 are ignored as they are negligible in comparison. The parallel-plate piston, which acts as a time-varying capacitor with static capacitance C₀ in the electrical domain, is connected to an inductor L and resistor R of the electrical resonating assembly 300 (representing the total electrical resistance in the circuit including parasitic resistance) to form a series RLC circuit driven by the driving mechanism 400, here shown as voltage source. Note (that the mechanical resonance frequency of the parallel plate piston is (ωₘ=\sqrt{k/m}) the mechanical Q-factor is (Qₘ=ωₘm/b), the electrical resonance frequency of the RLC circuit is (ωₑₗ=1/\sqrt{LC₀}), and the electrical Q-factor is (Qₘ=ωₑₗL/R) Mathematically, the 1-D model can be expressed by the following coupled second-order ordinary differential equations (ODEs):

$$[ \frac{{d}^{2}}{d {t}^{2}} + \frac{b}{m} \frac{d}{d t} + \frac{k}{m} ] x = \frac{{ε}_{0} A}{2 m} \frac{{V}_{c}^{2}}{{( {d}_{0} - x )}^{2}} \qquad ( Equation 1 )$$

$$[ \frac{{d}^{2}}{d {t}^{2}} + \frac{R}{L} \frac{d}{d t} + \frac{{d}_{0} - x}{L A {ε}_{0}} ] {V}_{c} = \frac{{d}_{0} - x}{L A {ε}_{0}} {V}_{i n} sin ( {ω}_{i n} t ) \qquad ( Equation 2 )$$

where Equation 1 represents the dynamics of the mechanical resonator and Equation 2 represents the electrical resonator. d₀ represents the initial gap between the parallel plates of the piston, x represents and the displacement of the piston, V_{c} is the voltage across the variable capacitor, A is the area of the piston, and ε₀ is the permittivity of free space.

The term on the right-hand side of Equation 2 represents the sinusoidal input voltage applied to the circuit having an amplitude Vᵢₙ and frequency ωᵢₙ (Note that in order to obtain Equation 2, it is assumed that the change in capacitance due to the motion of the plate is much smaller than the static capacitance, i.e., ΔC<<C₀). When the system parameters are selected such that the electrical resonance frequency is approximately half the mechanical resonance frequency (ωₑₗ≈ωₘ/2), the two resonators can be parametrically coupled to each other to enable non-linear modal interactions under certain input excitation conditions. These interactions result in the formation of frequency combs in the electrical as well as in the mechanical domain.

The transient response of the 1-D lumped parameter model is analyzed by solving the coupled equations numerically using a commercial solver such as MATLAB. However, this method of solution can be both non-intuitive and time consuming, especially when performing extensive parametric studies.

Alternately, the coupled ODEs can be re-written using new scaled and normalized parameters to make explicit a timescale separation, and approximated using an improved averaging theory (see, for example, J. A. Sanders, F. Verhulst, and J. Murdock, Averaging Methods in Non-linear Dynamical Systems, Vol. 59 (Springer, 2007); M. Tao, Simply Improved Averaging for Coupled Oscillators and Weakly Non-linear Waves, Communications in Non-linear Science and Numerical Simulation 71, 1 (2019)) to obtain approximate semi-analytical solutions. The semi-analytical solutions provide more insight into the operation of the proposed comb generation system by providing expressions for critical drive voltage and frequency comb spacing. These expressions can be used to explore the dependency of comb generation on a range of environmental and system parameters such as mechanical damping, electrical resistance, and operating frequency. Thus, analysis of the 1-D model using a combination of the complete numerical solution and the approximate semi-analytical techniques can be used to guide the selection of optimal operating parameters to generate stable frequency combs in different media.

### Mechanical Resonator Array

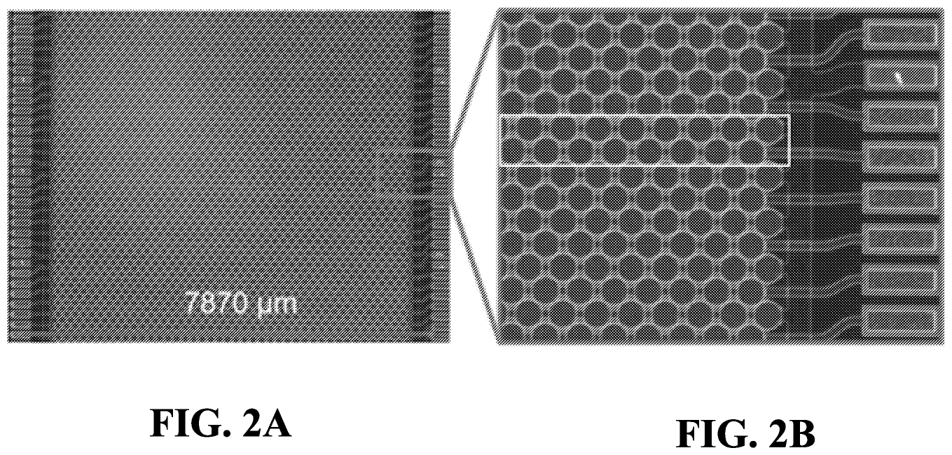

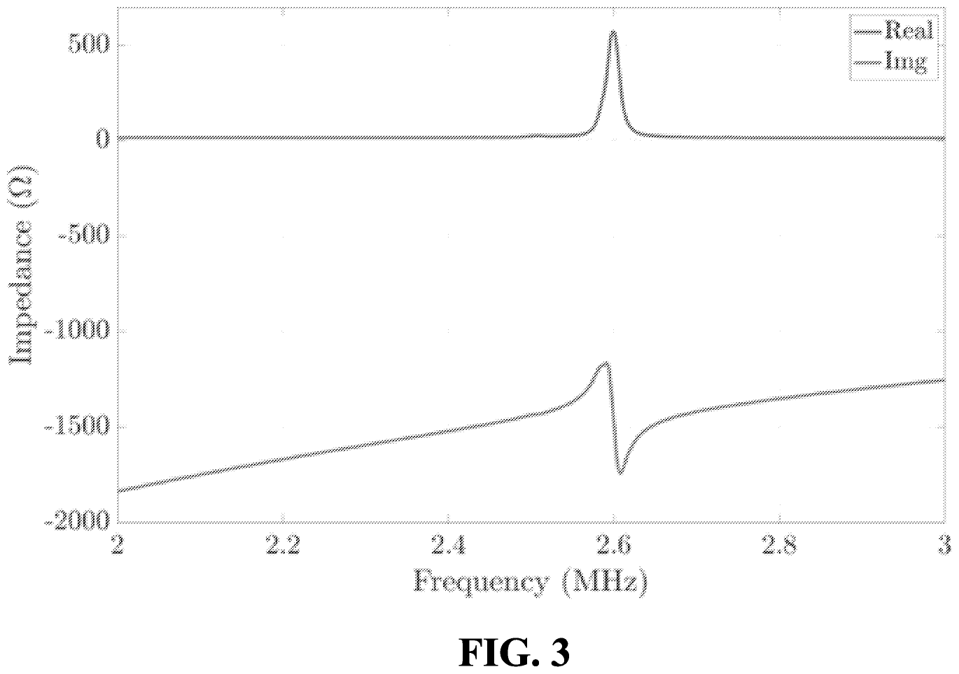

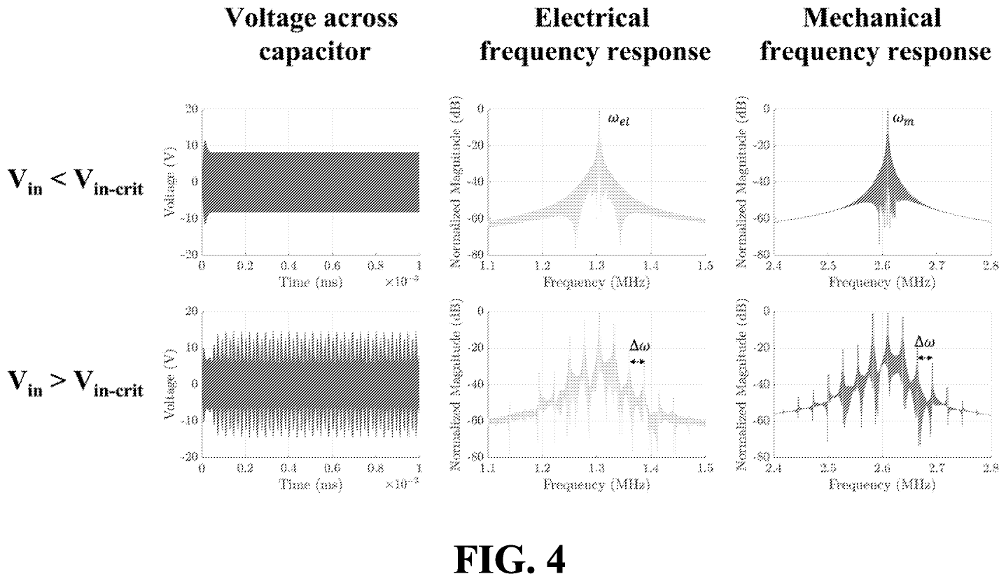

A capacitive MEM resonator array is used as a testbed to demonstrate the proposed approach to frequency comb generation. Such MEM resonator arrays have previously been used for chemical and biological sensing in both fluid and gas environments. Here, we use a commercially available (Phillips innovations) MEM array (FIGS. 2A-2B) consisting of 128 elements, with each element composed of 42 electrostatically actuated membrane-based drumhead resonators connected in parallel. The circular membranes measure 120 μm in diameter and are covered by a thin layer of metal to form a top electrode (FIG. 3).

All 128 elements are separated from a common bottom electrode by a vacuum-filled cavity measuring approximately 450 nm. This vacuum gap corresponds to the full range of mechanical motion of the membranes when they are electrostatically actuated using the top and bottom electrodes. Note that each membrane operates in its fundamental or first mode for the selected frequency range of operation. Furthermore, the operating frequency is selected such that it is far away from the band in which acoustic crosstalk is dominant, thereby ensuring that all the membranes in the array oscillate in-phase and higher order array modes are suppressed. As each individual metallized membrane forms a mini-capacitor with the bottom electrode, the MEM array also behaves as a time-varying capacitor and can be terminated with an inductor to realize an inductor-capacitor (LC) electrical resonator.

Two adjacent elements of the MEM array (highlighted by the outlined box in FIG. 2B) are connected in parallel to form the active mechanical resonator for the experiment. The corresponding mechanical and electrical parameters are characterized using a vector network analyzer (Agilent 8753ES) and shown in FIG. 3. The mechanical resonance frequency in air is measured to be 2.60 MHz when a 10 V DC bias is applied (note that the unbiased mechanical frequency of the resonator is closer to 2.61 MHz as the application of bias voltage leads to a reduction in resonance frequency due to spring softening).

The mechanical Q-factor estimated from the bandwidth of the resonance peak is approximately 200, reflecting the low damping experienced by the resonator in air. The static capacitance of the active elements can also be extracted by fitting a curve to the imaginary impedance and is found to be roughly 42 pF. The parameters extracted from the experimental device are used to fully model the electromechanical comb generation system in the numerical simulations and to inform the selection of electrical components in the experiment.

### Numerical Results

The 1-D model of the comb generation system described above is solved numerically using the parameters listed in TABLE 1 with the aim of investigating the influence of various system parameters and operating conditions on the formation of mechanical frequency combs.

TABLE 1
System Parameters Used In The Numerical Simulations

| Parameter | Symbol | Value |
|---|---|---|
| Equivalent Mass | m (Kg) | 1.1155 × 10⁻⁸ |
| Equivalent Stiffness | k (N/m) | 3 × 10⁶ |
| Equivalent Damping | b (N-s/m) | 9.1468 × 10⁻⁴ |
| Area of Plates | A (m²) | 2.08 × 10⁻⁶ |
| Gap Between Plates | d₀(m) | 450 × 10⁻⁹ |
| Resistance | R(Ω) | 60 |
| Inductance | L (H) | 3.6343 × 10⁻⁴ |
| Permittivity | ε₀ (F/m) | 8.854 × −10⁻¹² |

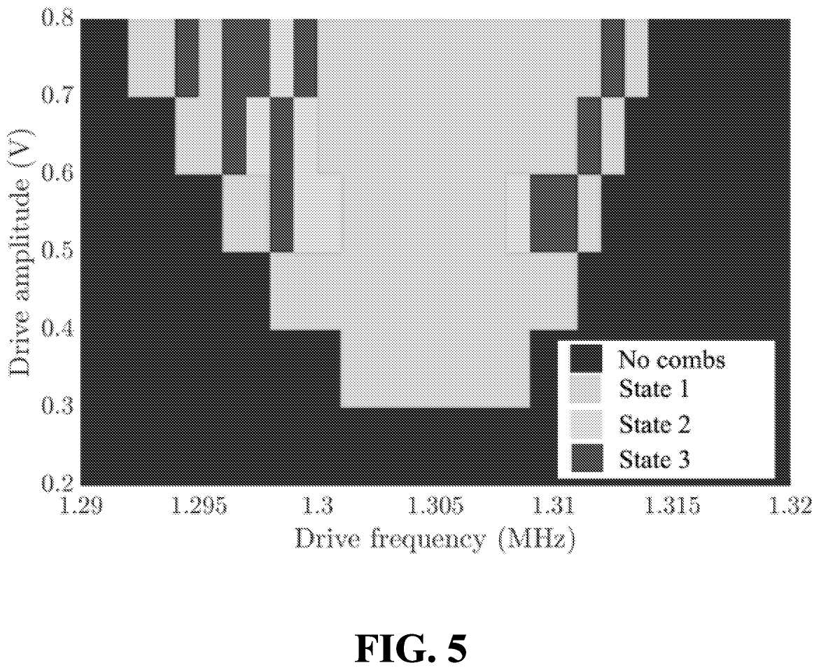

The input drive frequency and electrical circuit parameters are selected such that ωᵢₙ=ωₘ/2=ωₑₗ. This 2:1 resonance frequency relationship is intentionally selected to enable parametric coupling between the mechanical and electrical resonator. Equation 1 and Equation 2 are solved simultaneously using the ODE45 package in MATLAB, and the simulations results obtained are shown in FIG. 5. It is observed that for small values of input voltage Vᵢₙ, the solutions for the variables V_{c} and x i.e., the voltage across the capacitor and piston displacement, are purely harmonic oscillations at ωᵢₙ and 2ωᵢₙ respectively.

However, when Vᵢₙ exceeds a critical input threshold V_{in-crit}, a bifurcation appears and equally spaced spectral lines or frequency combs with spacing Δω are generated on either side of ωᵢₙ and 2ωᵢₙ, in both the mechanical and electrical domains. Additionally, the temporal response of the two oscillators takes the form of a pulse train having a beat frequency equal to Δω, which is characteristic of frequency comb generation systems.

The effect of detuning the input drive frequency from the electrical resonance frequency is studied by sweeping ωᵢₙ/2π from 1.29 MHz to 1.32 MHz (steps of 1 kHz) at different input drive levels (steps of 0.1 V). The coupled equations are solved for a fixed time of 1 ms with a step size of 25 ns at each discrete frequency and voltage value.

It can be seen in FIG. 5 that V_{in-crit} increases as ωᵢₙ is detuned either side of wₑₗ on the frequency axis. The shaded regions where frequency combs are generated are slightly asymmetric about web similar to an instability tongue seen in parametrically excited systems. The types of combs generated within this instability can be classified into three states, where State 1 represents the most commonly occurring stable frequency combs. The squares labelled as State 2 occur at higher levels of forcing and represent regions where higher-order frequency combs are generated, caused by the non-linear interaction of State 1 combs with each other. Finally State 3 represents frequency combs that demonstrate chaotic behavior. The transient response of the system at these frequencies is highly unstable and frequently resulted in the ODE45 solver crashing.

The semi-analytical solutions developed for Equation 1 and Equation 2 can be used to determine the impact of external operating conditions on frequency comb generation. The critical threshold value V_{in-crit}, can be numerically determined for a given set of system parameters and is found to be dependent on the mechanical damping b i.e., proportional to the reciprocal of the mechanical Q-factor.

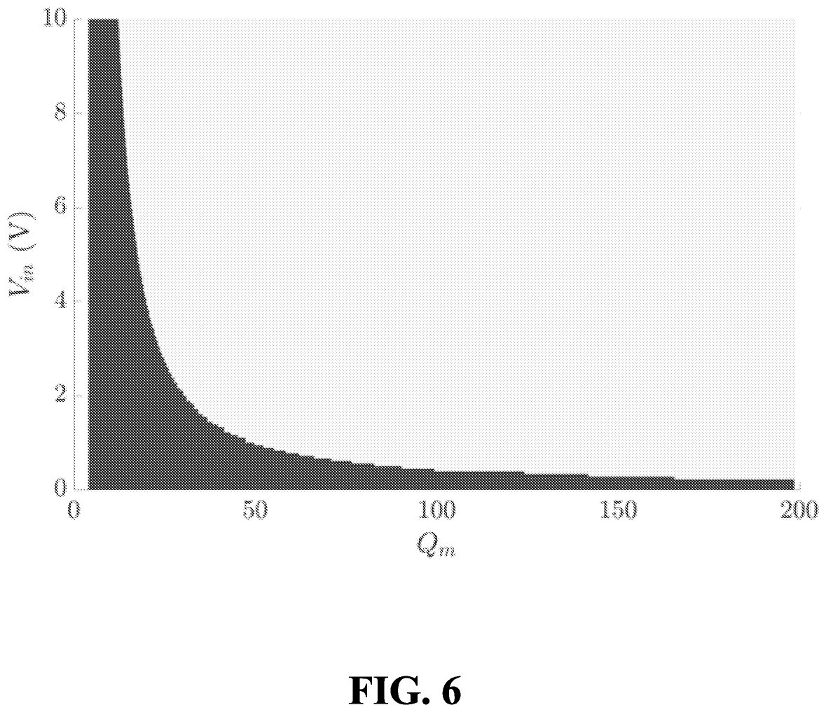

A map of the regions where frequency combs exist in the Vᵢₙ−Qₘ space when Qₑₗ=50 is shown in FIG. 6, with the lighter shaded region indicating the existence of combs. Here, the boundary separating the lighter region from the rest of the map represents V_{in-crit}, which increases dramatically with reduced Qₘ. While light damping might not impede the ability to generate frequency combs in air, the dependence of V_{in-crit} on b introduces a significant challenge while trying to generate combs using purely mechanical resonators in heavily damped media such as water and biofluids.

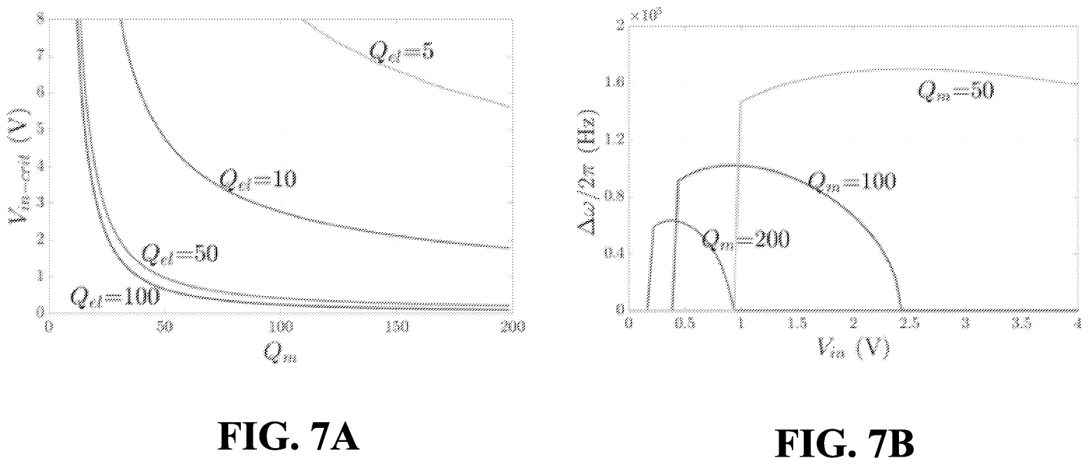

Fortunately, it is found that in the case of the parametrically coupled electrical-mechanical resonator, V_{in-crit} is a function of both mechanical damping and the resistance R in the electrical circuit. FIG. 7A shows how the critical input voltage required for parametric resonance reduces with increasing value of electrical quality factor Qₑₗ, for a fixed value of Qₘ. Hence maintaining a low value of R can partially mitigate the effect of mechanical damping on V_{in-crit} thereby allowing for practically achievable values of V_{in-crit} even at large values of b.

The semi-analytical solutions can also be used predict the spacing between the spectral lines, both as a function of the input drive voltage as well as environmental conditions. The frequency spacing Δω is plotted against Vᵢₙ for different values of Qₘ in figure FIG. 7B.

While Δω is initially zero at low values of input drive, a sudden jump or discontinuity in the curve is observed when Vᵢₙ=V_{in-crit}, indicating the onset of frequency comb generation. The spacing between the comb lines initially increases with increasing Vᵢₙ, before it reaches a maximum value and then gradually begins to decrease. Furthermore, the spacing between the combs also increases as the mechanical Q-factor is reduced, indicating that frequency combs spanning a larger bandwidth can be obtained in heavily damped environments. It is important to note here that the semi-analytical solutions are approximate solutions to Equation 1 and Equation 2 and as such are not accurate, especially for Vᵢₙ>>V_{in-crit}. They are better suited to qualitatively inform trends as opposed to quantitative predictions which require one to fully solve the coupled equations.

Hence the 1-D model allows for the investigation of the operational characteristics of the present electromechanical comb generation system. The semi-analytical solutions shed light on how different operating conditions including mechanical and electrical damping affect frequency comb generation and the comb spacing, while suggesting that careful selection of parameters can lower the critical drive voltage required for comb generation. Since the electrical resistance in a circuit can be easily minimized by various active and passive methods, the present system can potentially be utilized for mechanical frequency comb generation in hitherto inaccessible damped fluid environments.

### Experimental Results

The results of the numerical analysis are experimentally verified by operating the MEM array in different media, starting with air. The MEM array is terminated with wire-wound inductor of suitable inductance such that the electrical resonance frequency of the LC circuit is half the unbiased mechanical frequency, i.e., ωₑₗ≈ωₘ/2=1.305 MHz. Note that circuit components with the lowest series resistance are chosen to minimize the total loss in the electrical resonator, such the electrical Q-factor is approximately 50.

The circuit is then driven by a tone-burst (10 ms ON, 2% duty cycle) from a signal generator (Agilent 33250a) through an RF amplifier for

$$1.2 \; 95 MHz \leq \frac{{ω}_{i n}}{2 π} \leq 1.3 \; 08 MHz$$

and the voltage across the MEMS array is recorded. It is found that at low values of Vᵢₙ that frequency spectrum of V_{c} consists primarily of the ωᵢₙ/2π component. However, as the level of Vᵢₙ is increased and crosses the critical threshold (V_{in-crit}=0.4 V), spectral components at (ωᵢₙ∓nΔω)/2π begin to appear on either side of the drive tone where n is an integer representing the number of sidebands.

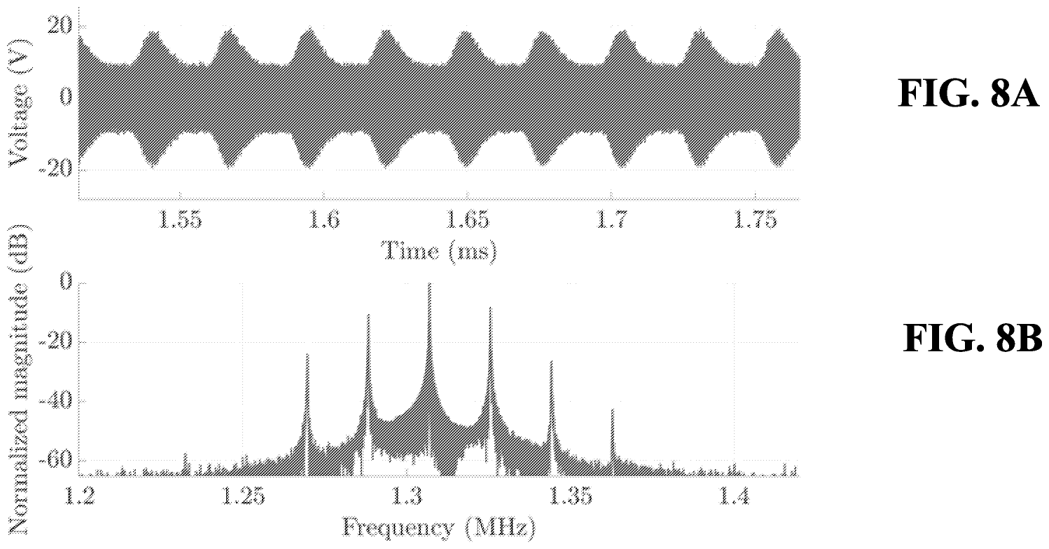

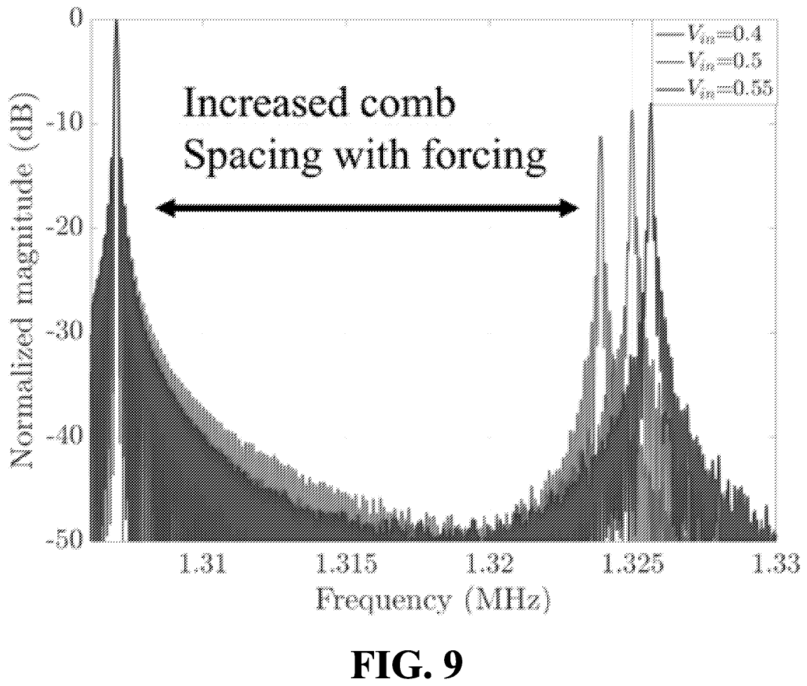

As expected, the time domain signal takes the form of a pulse train as seen in FIGS. 8A and 8B. It is observed that further increasing Vᵢₙ beyond V_{in-crit} results in two phenomena—first, the number of sidebands increases as the input voltage is increased. Secondly it is seen that the frequency spacing between the spectral lines increases with Vᵢₙ as predicted by the numerical simulations (FIG. 9). This increase in spacing is not linear, with the sharpest change being observed closer to V_{in-crit}, followed by a plateau before eventually reducing at high input voltage levels.

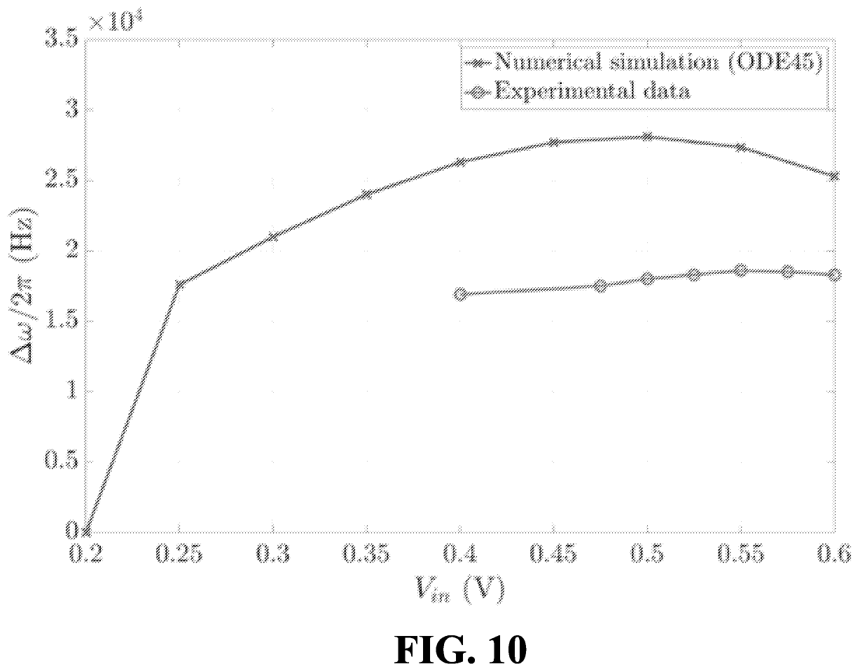

Further increasing Vᵢₙ causes non-linear interactions between the lines, leading to the formation of higher order combs that results in a highly unstable signal. In order to verify the relation between line spacing and Vᵢₙ, the coupled equations are numerically solved using ODE45 and the results are compared with the experimental data (FIG. 10). It is found that simulations and experimental data showed a close match, where the offset between the simulated and experimental Δω can be attributed to non-uniformities in fabrication and parasitic capacitance in the experimental device.

Thus, a single drive tone with Vᵢₙ>V_{in-crit} is sufficient to generate stable frequency combs in the proposed system under lightly damped conditions. The spacing between the spectral lines is directly dependent on Vᵢₙ, which essentially acts as an electrostatic force on the mechanical resonator. Hence, by operating the system at a fixed Vᵢₙ, the change in line spacing can be used to directly determine an increment in force or mass acting on the mechanical resonator. Unlike conventional force sensing resonators that require complex electronic feedback loops to track changes in frequency, the present system can be monitored by simply tracking the beat frequency using a frequency counter.

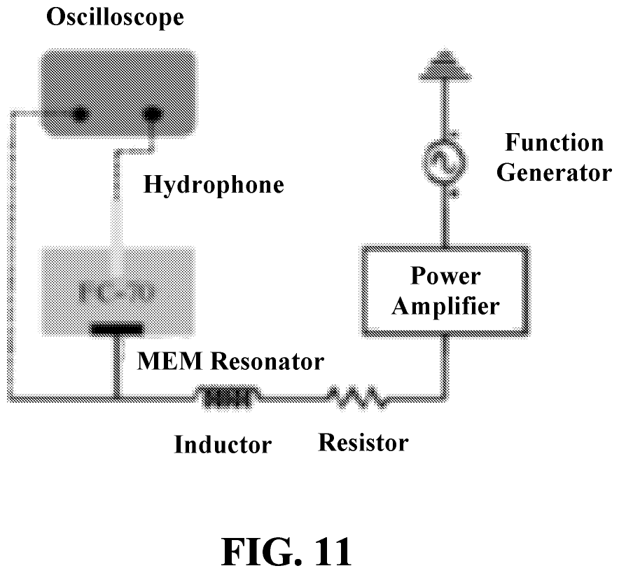

The same MEM array is next immersed in non-conductive water-like liquid (Fluorinert-FC 70, Sigma Aldrich) to study the effect of increased mechanical damping on the generation of frequency combs. The experimental setup used in the investigation is shown in FIG. 11.

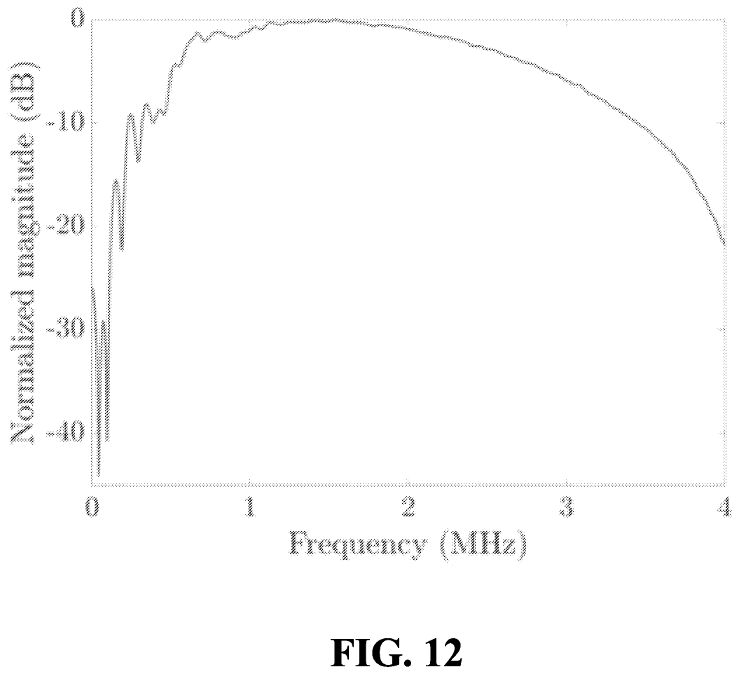

The frequency response of the mechanical resonator in immersion is first characterized by applying a 50 ns unipolar pulse from a signal generator to the array. The impulse response of the resonator is recorded using a broadband hydrophone (Onda Corp.) and from the FFT of the signal (FIG. 12), it is seen that the 3-dB bandwidth is 3.15 MHz and the mechanical Q-factor is less than 1 when operating in immersion.

The additional mass loading and increased damping experienced by the resonator, in contrast to operation in air, leads to a reduction in the mechanical resonance frequency to approximately 1.7 MHz, so the value of the series inductor is adjusted such the new electrical resonance frequency is 850 kHz (ωₑₗ≈ωₘ/2).

The system is first driven by a single electrical drive tone at ωᵢₙ/2π=850 kHz and the spectrum of the signal received by the hydrophone is monitored for increasing drive amplitude levels. It is observed that for all input drive levels, the output spectrum consists purely of the ωᵢₙ/π component and no additional spectral lines are observed. This can be explained by the fact that when the resonator operates in immersion, the increased damping causes V_{in-crit} to exceed the maximum operating voltage of the resonator—as a result, frequency combs are not generated when the resonator is driven by a single drive tone in an open liquid domain.

Alternately, the case of a resonator operating in a fluid with a rigid boundary is considered, as many biosensing applications consist of an enclosed microfluidic channel through which a fluid of interest is flown and the sensing element is placed inline along the channel.

Instead, two input drive tones of equal amplitude ωᵢₙ₁ and ωᵢₙ₂ (ωᵢₙ₁/π=820 kHz, ωᵢₙ₂/π=880 kHz, Δω=60 kHz) are applied to the system and the input drive strength is gradually increased. At low input drive levels, the output spectrum contains components at 2ωᵢₙ₁, 2ωᵢₙ₂ and ωᵢₙ₁+ωᵢₙ₂, that are generated due to the voltage-squared dependence of the MEM resonator (see Equation 1).

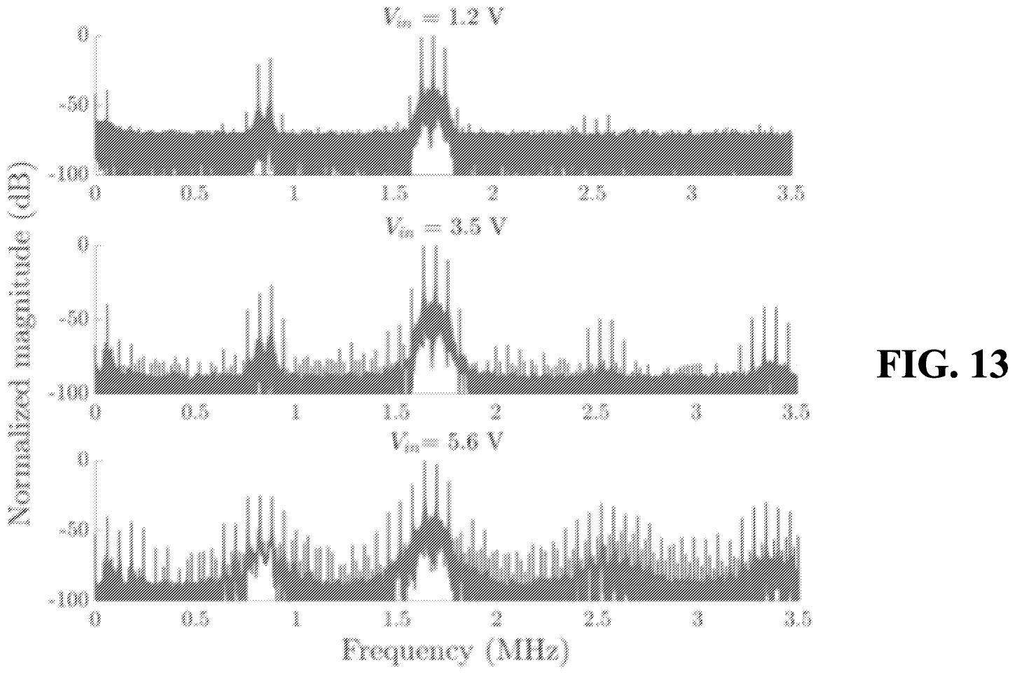

At higher input drive levels, an increasing number of spectral lines spaced apart by 60 kHz are generated on either side of at 2ωᵢₙ₁ and 2ωᵢₙ₂ (FIG. 13). A similar approach of using two drive tones to generate electromechanical frequency combs in a resonator has been previously reported and is governed by a parametric 4-wave mixing process. However, the combs generated in earlier demonstrations are confined to a narrow bandwidth within the vibrational mode of a high-Q resonator.

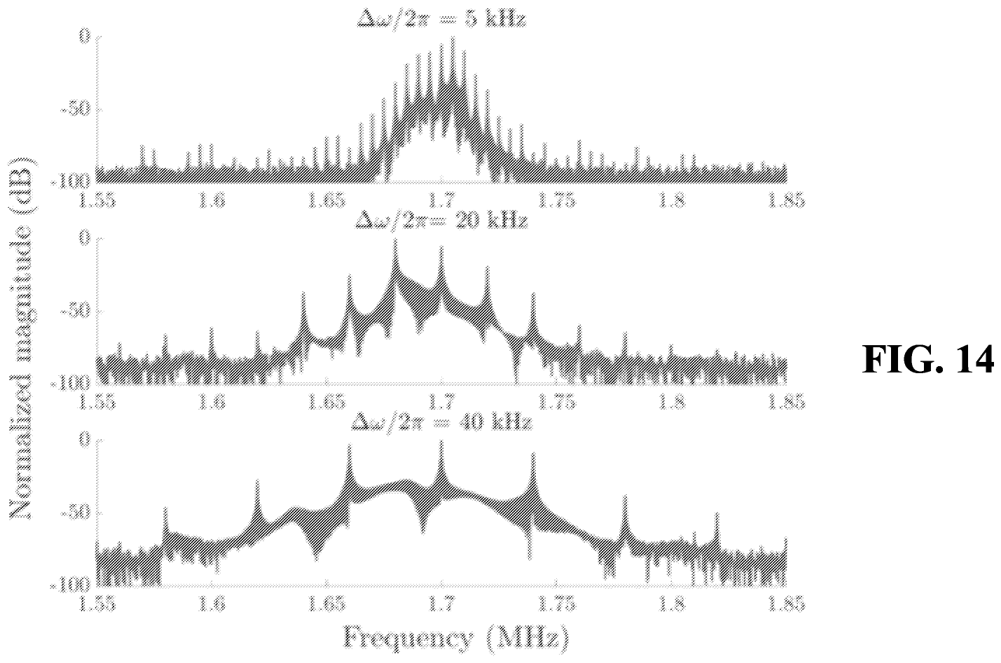

The broadband characteristics of our MEM array, coupled with the reduced electrical resistance in the LC circuit, enables the generation of equally spaced spectral lines spanning over an octave in the frequency scale. It can be observed in FIG. 14 that the repetition rate of the combs can be also controlled by simply changing the frequency spacing Δω between the input drive tones. More significantly, Δω can be made arbitrarily large or small, as long as the input drive level meets the required conditions to enable the parametric mode coupling required for comb generation. The ability to easily generate tunable, broadband and coherent frequency combs in a damped environment potentially allows the proposed system to be used for precise distance measurement in the short to medium range in fluid.

In addition to being able to generate frequency combs with a fixed repetition rate using two input drive tones, it would be tremendously useful to generate combs in liquid using a single input drive, in which the spacing between the spectral lines are a function of the force acting on the mechanical resonator. Many biosensing applications consist of an enclosed microfluidic channel through which a fluid of interest is flown, and the sensing element is placed inline along the channel.

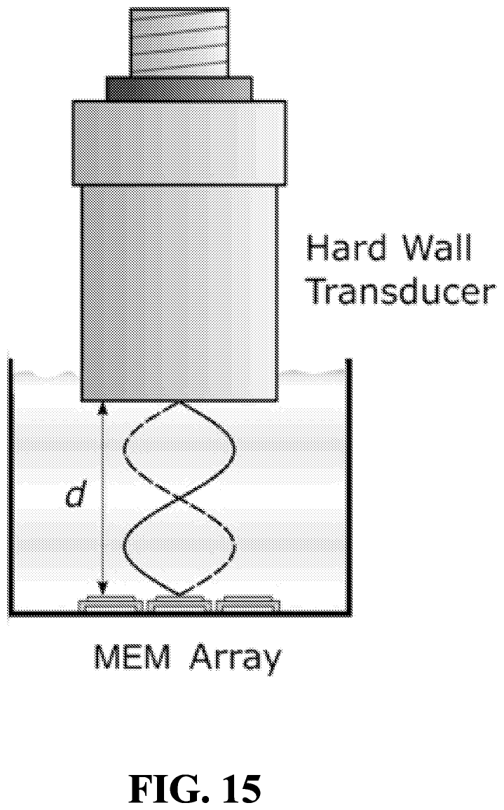

To simulate similar boundary conditions, a MEM array is fixed to the bottom of a container filled with FC-70 and a piezoelectric transducer is placed above at a distance d, with its flat face parallel to the array surface (FIG. 15). The face of the transducer acts as a hard wall or reflector mimicking the walls of a microfluidic channel and enables the formation of acoustic standing waves between the MEM array and the piezo transducer. These high-Q factor standing wave resonances can be exploited as the primary vibrational mode of the mechanical resonator to generate frequency combs with a single drive tone in liquid.

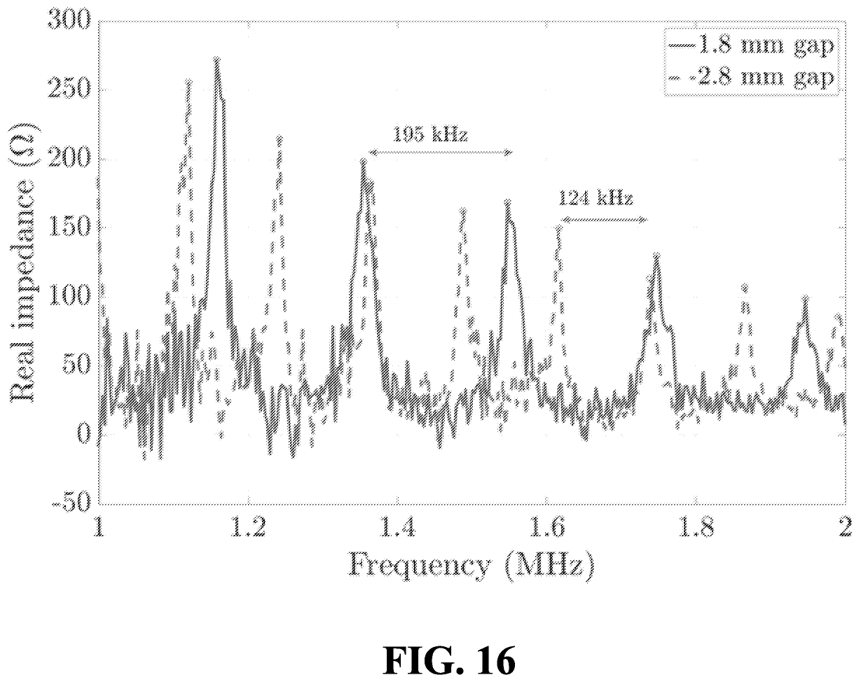

As the vertical distance d can be adjusted by a screw gauge micrometer, the position and frequency spacing between the standing waves can be manually tuned to a desired value as seen in FIG. 16. The screw gauge is adjusted to obtain a spacing of d=1.8 mm and a standing wave resonance (Qₘ≈13) is generated at 1.15 MHz (c_{FC-70}=687 m/s). The electrical circuit is tuned to half of this frequency (ωₑₗ=575 kHz) and the system is driven with a single tone at ωᵢₙ=ωₑₗ.

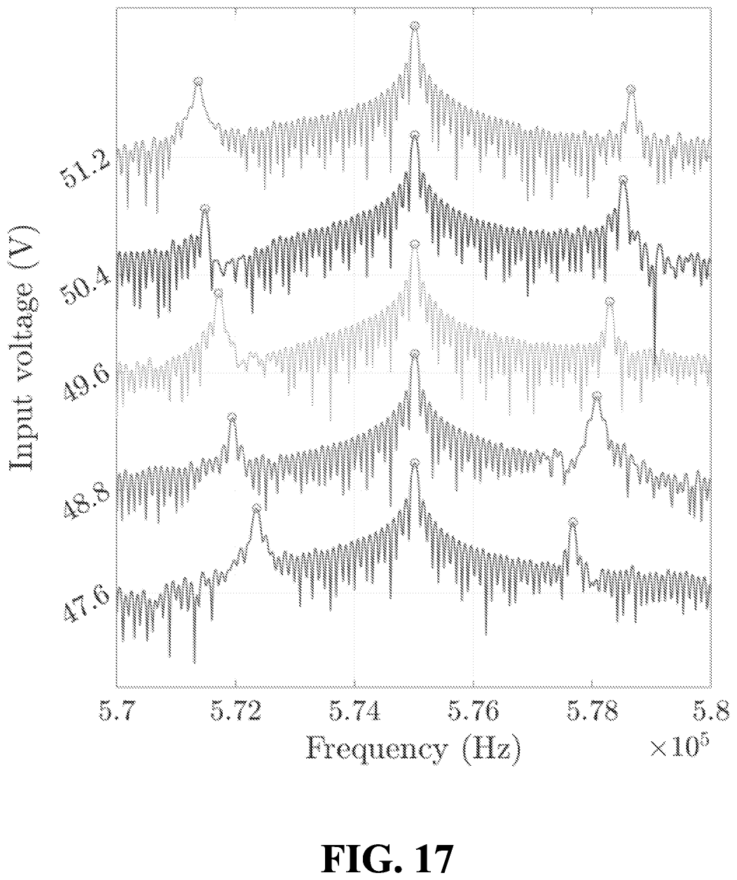

Similar to the behavior in air, it is observed in FIG. 17, that additional evenly spaced spectral lines begin to appear on either side of ωₑₗ as the input drive is increased above V_{in-crit}=46 V. The spacing between the spectral lines also increases with higher input voltage levels, confirming the dependency of line spacing on the force experienced by the mechanical resonator.

Despite the larger damping experienced in immersion, the confinement of energy within a high-Q standing wave mode enables the generation of electromechanical frequency combs using a single drive tone, in an enclosed fluid-filled channel. The change in spectral line spacing with increasing forcing further indicates that the generated combs can be used to sense fluid properties or mass of particles in solution in a simple manner without fabrication of complex resonator arrays.

To highlight the advantage of comb-based sensing over conventional resonance spectroscopy when interrogating bulk fluid properties in microfluidics, we simulate and compare the frequency response of a linear resonator to a frequency comb generating resonator, when operating in a 200 μm high, fluid-filled channel. The methods of solution described above cannot be used to solve this particular problem due to the non-trivial boundary conditions—instead we employ a previously used technique that makes use of SIMULINK.

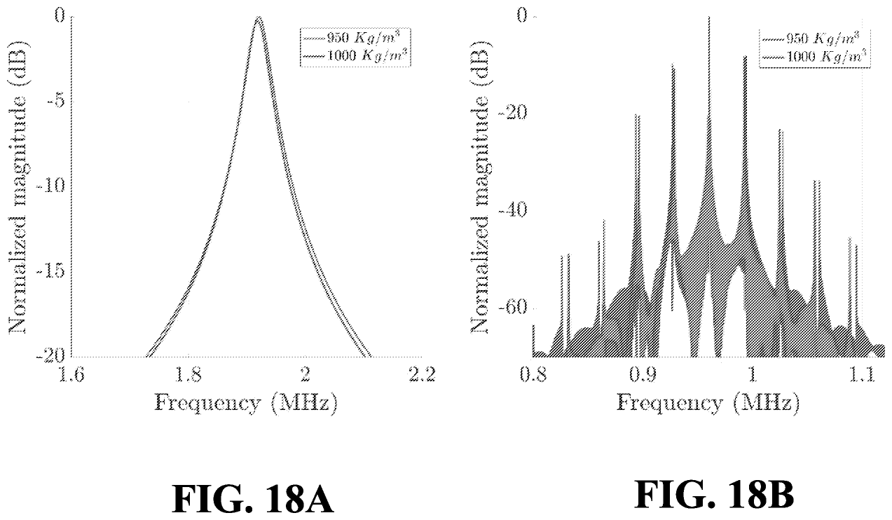

The sensitivity of the resonator to a 5% change in fluid density is evaluated when operating in these two distinct modes, and the results are shown in FIGS. 18A-18B. It is observed that in the linear case, the density change produces a negligible shift in both the amplitude and frequency the resonant peak, partly as the low-Q frequency response makes it challenging to accurately detect the peak shift. The time of flight or spacing between the standing wave resonances cannot be used either as the speed of sound of the medium is held constant. However, a clear and distinguishable separation between the spectral lines for the two different fluid densities can be observed when the resonator is configured to generate frequency combs (the recording length or gate time here is 5 ms).

Inherently, the system acts as an amplitude to frequency converter, where the change in operating point on the linear frequency response curve is expressed as a shift in the spectral line spacing. Furthermore, the frequency shift Δω is multiplied by a factor n (where n represents the number of spectral lines formed on either side of the driving frequency) as we move away from the central spectral line, resulting in improved sensitivity with a greater number of frequency combs.

For example, a frequency spacing of 3 kHz can be observed at the 2^{nd} spectral line from the center, whereas a spacing of 6 kHz is observed at the 4^{th} spectral line, for the same change in density.

It is important to point out that the spectral line width can be further reduced by increasing the gate width or acquisition time. The collection of a larger number of data points in the time domain improves the resolution of the combs in the frequency domain, thus enabling higher sensor resolution at the cost of a longer acquisition time. The sensitivity of the comb-based system can also be improved by generating a larger number of equidistant spectral lines on either side of the drive tone, as shown in the simulation. Increasing the strength of the drive tone increases the signal-to-noise ratio (SNR) of the sidebands, however, there is an upper limit on the drive strength beyond which the generated combs become unstable.

Alternately, tuning the bandwidth of the input excitation signal or modifying the non-linearity that mediates frequency mixing could potentially enable broadband spectral lines as seen in OFCs. Thus, the potential of mechanical comb-based techniques for fluidic measurements and spectroscopy is demonstrated. Further improvements in resolution and sensitivity can be made possible by optimizing the driving voltage and other system parameters, with the ultimate system resolution eventually limited by effects such as thermal fluctuations, external mechanical vibrations and phase noise.

As disclosed herein, we demonstrate the generation of stable electromechanical frequency combs in air and liquid by using a MEM array parametrically coupled to an electrical resonator. A 1-D lumped parameter model of the proposed system is presented, and approximate semi-analytical solutions are developed, that allow the investigation of system parameters influencing frequency comb generation. Numerical simulations reveal that the critical input voltage required to generate frequency combs is a function of both the mechanical Q-factor and electrical Q-factor.

In contrast to purely mechanical resonator-based frequency comb generation methods, the initiation threshold in the proposed system can be lowered by reducing the electrical resistance using passive or active methods, thereby enabling frequency comb formation even in highly damped environments. The results obtained by numerical simulations are experimentally validated using a commercially available MEM resonator terminated with a wire-wound inductor. Frequency combs with a repetition rate sensitive to the force on the mechanical resonator are generated with a single electrical input drive in air and in an enclosed fluid-filled microfluidic channel.

The advantage of our approach in sensing applications is highlighted by comparing the performance of a comb-based sensor with conventional resonance spectroscopy when interrogating bulk fluid properties. Thus, the ability to generate stable and tunable electromechanical combs in fluids enables several applications previously inaccessible to optical combs. Future work will be focused on optimizing the proposed system for applications in microfluidic particle detection. The generation of frequency combs in an open fluid domain using a single drive tone will also be explored.

In this description, numerous specific details have been set forth. It is to be understood, however, that implementations of the disclosed technology can be practiced without these specific details. In other instances, well-known methods, structures and techniques have not been shown in detail in order not to obscure an understanding of this description. References to “one embodiment,” “an embodiment,” “some embodiments,” “example embodiment,” “various embodiments,” “one implementation,” “an implementation,” “example implementation,” “various implementations,” “some implementations,” etc., indicate that the implementation(s) of the disclosed technology so described can include a particular feature, structure, or characteristic, but not every implementation necessarily includes the particular feature, structure, or characteristic. Further, repeated use of the phrase “in one implementation” does not necessarily refer to the same implementation, although it can.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

While certain implementations of the disclosed technology have been described in connection with what is presently considered to be the most practical and various implementations, it is to be understood that the disclosed technology is not to be limited to the disclosed implementations, but on the contrary, is intended to cover various modifications and equivalent arrangements included within the scope of the appended claims. Although specific terms are employed herein, they are used in a generic and descriptive sense only and not for purposes of limitation.

This written description uses examples to disclose certain implementations of the disclosed technology, including the best mode, and also to enable any person skilled in the art to practice certain implementations of the disclosed technology, including making and using any devices or systems and performing any incorporated methods. The patentable scope of certain implementations of the disclosed technology is defined in the claims, and can include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A resonator-based comb generation system configured for stable frequency comb generation in a media environment across a range of media environment densities.

2. The system of claim 1, wherein the system is configured for stable frequency comb generation in the media environment having a density ranging from about 900 to about 1100.

3. The system of claim 1 comprising a coupled resonant mechanical assembly and resonant electrical assembly.

4. The system of claim 1 comprising a non-linearly coupled resonant mechanical assembly and resonant electrical assembly.

5. The system of claim 1 comprising a resonant mechanical assembly coupled to two or more resonant electrical assemblies.

6. The system of claim 1, wherein the system is driven to parametric resonance.

7. The system of claim 1, wherein the system is driven to parametric resonance by an input selected from the group consisting of a mechanical input, an audio input, and a combination thereof.

8. The system of claim 3 further comprising a driving mechanism configured to drive the system into parametric resonance.

9. The system of claim 6, wherein an initiation threshold for parametric resonance is variable.

10. The system of claim 6, wherein an initiation threshold for parametric resonance is lowered by reducing an electrical resistance of the system.

11. A system configured for frequency comb generation in a media environment across a range of media environment densities comprising:
a resonant mechanical assembly; and
a resonant electrical assembly;
wherein the assemblies are non-linearly coupled.

12. The system of claim 11, wherein the system is driven to parametric resonance; and
wherein an initiation threshold for parametric resonance is selected form the group consisting of:
being variable;
being lowered by reducing an electrical resistance of the system; and
a combination thereof.

13. The system of claim 11, wherein the system is driven to parametric resonance by an input selected from the group consisting of a mechanical input, an audio input, and a combination thereof.

14. The system of claim 11 further comprising a driving mechanism configured to drive the system into parametric resonance.

15. The system of claim 11 further comprising a second resonant electrical assembly;
wherein each resonant electrical assembly is non-linearly coupled to the resonant mechanical assembly.

16. The system of claim 11, wherein the frequency combs are selected from the group consisting of acoustic frequency combs, mechanical frequency combs, phononic frequency combs, and a combination thereof.

17. The system of claim 11, wherein the resonant mechanical assembly comprises a microelectromechanical (MEM) resonator; and
wherein the resonant electrical assembly comprises a resonant electrical circuit.

18. An electromechanical system for frequency comb generation comprising a coupled resonant mechanical assembly and resonant electrical assembly;
wherein the system is configured to generate stable frequency combs while operating in a media environment across a range of media environment densities; and
wherein the system is driven to parametric resonance by one or more inputs.

19. The system of claim 18, wherein the system is configured to generate stable frequency combs while operating in the media environment having a media environment density greater than about 1.2 kg/m³.

20. The system of claim 18, wherein the system is configured to generate stable frequency combs while operating in the media environment having a media environment density greater than about 10 kg/m³.

21. The system of claim 18, wherein the system is configured to generate stable frequency combs while operating in the media environment having a media environment density greater than about 50 kg/m³.

22. The system of claim 18, wherein the system is configured to generate stable frequency combs while operating in the media environment having a density ranging from about 900 kg/m³ to about 1100 kg/m³.

23. The system of claim 18, wherein the resonant electrical assembly comprises an RLC circuit.

24. The system of claim 18, wherein one or more of the inputs drive an electrical parameter of the resonant electrical assembly.

25. The system of claim 18, wherein one or more of the inputs drive a voltage of the resonant electrical assembly.

26. The system of claim 18, wherein one or more of:
the resonant mechanical assembly and resonant electrical assembly are non-linearly coupled;
the system further comprises a second resonant electrical assembly, wherein each resonant electrical assembly is coupled to the resonant mechanical assembly;
a mechanical resonance frequency of the resonant mechanical assembly is approximately equal to twice an electrical resonance frequency of the resonant electrical assembly;
the system is configured to generate stable frequency combs in a liquid;
at least one of the inputs is selected from the group consisting of a mechanical input, an audio input, and a combination thereof;
an initiation threshold for parametric resonance is selected form the group consisting of:
being variable;
being lowered by reducing an electrical resistance of the system; and
a combination thereof; and
the frequency combs are selected from the group consisting of acoustic frequency combs, mechanical frequency combs, phononic frequency combs, and a combination thereof.

27. The system of claim 18 further comprising a driving mechanism configured to drive the system into parametric resonance;
wherein the resonant mechanical assembly comprises a MEM resonator;
wherein the resonant electrical assembly comprises a resonant electrical circuit comprising electrical elements;
wherein the MEM resonator terminates with one or more of the electrical elements of the resonant electrical circuit; and
wherein the driving mechanism drives one or more of the electrical elements with one or more electrical tones.

28. The system of claim 18, wherein the resonant mechanical assembly has a mechanical Q-factor in the media environment;
wherein the resonant electrical assembly has an electrical Q-factor in the media environment; and
wherein the system is configured to generate the stable frequency combs while operating in the media environment in a range of mechanical Q-factor from about 25 to about 200.

29. The system of claim 28, wherein the system is configured to generate the stable frequency combs while operating in the media environment in a range of mechanical Q-factor lower than 100.
